(19) United States
(12) Patent Application Publication
(10) Pub. No.: US 2025/0393417 A1
(43) Pub. Date: Dec. 25, 2025

(54) DISPLAY DEVICE

(71) Applicant: Samsung Display Co., LTD., Yongin-si (KR)

(72) Inventors: Jin Sung AN, Yongin-si (KR); Sung Ho KIM, Yongin-si (KR); Se Wan SON, Yongin-si (KR); Wang Woo LEE, Yongin-si (KR)

(21) Appl. No.: 19/015,394

(22) Filed: Jan. 9, 2025

(30) Foreign Application Priority Data
Jun. 24, 2024 (KR) 10-2024-0081862

(51) Int. Cl. H10K 59/131; H10K 59/121; H10K 59/124

(52) U.S. Cl. CPC H10K 59/131; H10K 59/1216; H10K 59/124

(57) ABSTRACT

A display device may include a substrate, a lower conductive layer above the substrate, and including a first layer including a first metal, and a second layer below the first layer and including a second metal different from the first metal, the first layer having a tip shape in which the first layer protrudes laterally further than the second layer at an edge of the lower conductive layer, a first insulating pattern above the lower conductive layer, and overlapping the edge of the lower conductive layer, a first insulating layer above the lower conductive layer and the first insulating pattern, and an upper conductive layer overlapping the lower conductive layer with the first insulating layer therebetween to provide a first capacitor.

### CROSS-REFERENCE TO RELATED APPLICATION

The present application claims priority to, and the benefit of, Korean Patent Application No. 10-2024-0081862, filed on Jun. 24, 2024, in the Korean Intellectual Property Office, the entire disclosure of which is incorporated herein by reference.

### BACKGROUND

### 1. Field

The present disclosure relates to a display device.

### (b) Description of the Related Art

A display device is a device that displays an image, and a light-emitting diode display device has been recently attracting attention as a self-light-emitting diode display device.

The light-emitting diode display device may have a self-light-emitting characteristic, and unlike a liquid crystal display device, the light-emitting diode display device may be suitable not to have a separate light source, so that a thickness and a weight of the display device are reduced. In addition, the light-emitting diode display device exhibits high-quality characteristics, such as low power consumption, high luminance, high response speed, and/or the like.

In general, the light-emitting diode display device may include a plurality of pixels, and each pixel may include a pixel circuit portion including a plurality of transistors and a light-emitting element. The plurality of transistors of the pixel circuit portion may be connected to one or more suitable signal lines including a data line and a voltage line, and may transfer a driving current to the light-emitting element. The light-emitting element may include an anode and a cathode, and the anode may be connected to the transistor of the pixel circuit portion to receive the driving current.

### SUMMARY

Aspects of one or more embodiments are directed toward a display device that improves display quality by preventing or reducing leakage between a conductive layer that provides a capacitor included in a pixel circuit portion of a display device and another conductive layer.

Additional aspects will be set forth in part in the description which follows and, in part, will be apparent from the description, or may be learned by practice of the presented embodiments of the disclosure.

According to one or more embodiments, a display device may include a substrate, a lower conductive layer above the substrate, and including a first layer including a first metal, and a second layer below the first layer and including a second metal different from the first metal, the first layer having a tip shape in which the first layer protrudes laterally further than the second layer at an edge of the lower conductive layer, a first insulating pattern above the lower conductive layer, and overlapping the edge of the lower conductive layer, a first insulating layer above the lower conductive layer and the first insulating pattern, and an upper conductive layer overlapping the lower conductive layer with the first insulating layer therebetween to provide a first capacitor.

The first insulating pattern may be spaced from a central portion of the lower conductive layer in plan view.

The first insulating pattern may extend along the edge of the lower conductive layer to provide a closed curved band shape.

The first insulating pattern may include an organic insulating material, wherein the first insulating layer includes an inorganic insulating material.

A thickness of the first insulating pattern may be greater than a thickness of the first insulating layer.

The thickness of the first insulating pattern may be about 1 micrometer to about 1.5 micrometer.

The first layer may include titanium (Ti), wherein the second layer includes aluminum (Al).

The lower conductive layer may include a first capacitor electrode, wherein the upper conductive layer includes a first voltage line, and wherein the first capacitor electrode and the first voltage line overlap to provide the first capacitor.

The display device may further include a second insulating pattern above the upper conductive layer, and overlapping an edge of the upper conductive layer, a second insulating layer above the upper conductive layer and the second insulating pattern, and a second capacitor electrode above the second insulating layer, wherein the upper conductive layer includes a third layer including a third metal, and a fourth layer below the third layer and including a fourth metal different from the third metal, wherein the third layer has a tip shape in which the third layer protrudes laterally further than the fourth layer at the edge of the upper conductive layer, and wherein the second capacitor electrode overlaps the upper conductive layer with the second insulating layer therebetween to provide a second capacitor.

The second insulating pattern may be spaced from a central portion of the upper conductive layer in plan view.

The second insulating pattern may extend along the edge of the lower conductive layer to provide a band shape.

The second insulating pattern may include an organic insulating material, wherein the second insulating layer includes an inorganic insulating material.

A thickness of the second insulating pattern may be greater than a thickness of the second insulating layer.

The thickness of the second insulating pattern may be about 1 micrometer to about 1.5 micrometer.

The third layer may include titanium (Ti), wherein the fourth layer includes aluminum (Al).

The second capacitor electrode and the first voltage line may overlap to provide the second capacitor.

According to one or more embodiments, a display device may include a substrate, pixel circuit portions that are above the substrate, a voltage line that is electrically connected to the pixel circuit portions, an input capacitor electrode that overlaps the voltage line with an insulating layer therebetween to provide a capacitor, and an insulating pattern that overlaps at least one edge of the input capacitor electrode and the voltage line, wherein at least one of the input capacitor electrode or the voltage line includes a first layer including a first metal, and a second layer below the first layer and including a second metal different from the first metal, the first layer having a tip shape in which the first layer protrudes laterally further than the second layer, and the input capacitor electrode having an island shape in the pixel circuit portions.

The insulating pattern may be spaced from at least one central portion of the input capacitor electrode or the voltage line in plan view.

The insulating pattern may extend along the at least one edge of the input capacitor electrode and the voltage line to provide a band shape.

The insulating pattern may include an organic insulating material, wherein the insulating layer includes an inorganic insulating material.

According to one or more embodiments, an electronic device may include a display device including a substrate, a lower conductive layer above the substrate, and including a first layer including a first metal, and a second layer below the first layer and including a second metal different from the first metal, the first layer having a tip shape in which the first layer protrudes laterally further than the second layer at an edge of the lower conductive layer, a first insulating pattern above the lower conductive layer, and overlapping the edge of the lower conductive layer, a first insulating layer above the lower conductive layer and the first insulating pattern, and an upper conductive layer overlapping the lower conductive layer with the first insulating layer therebetween to provide a first capacitor.

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

### BRIEF DESCRIPTION OF THE DRAWINGS

FIG. 1 is an equivalent circuit diagram of one pixel of a display device according to one or more embodiments.

FIG. 2 is a timing diagram of a signal applied to the pixel shown in FIG. 1.

FIG. 3, FIG. 6, FIG. 9, FIG. 12, FIG. 15, FIG. 19, and FIG. 25 are each a plan view of sequential lamination operations of a manufacturing method of the display device according to one or more embodiments.

FIG. 4 is a cross-sectional view of the display device shown in FIG. 3 cut along a line A1-A2.

FIG. 5 is a cross-sectional view of the display device shown in FIG. 3 cut along a line B1-B2.

FIG. 7 is a cross-sectional view of the display device shown in FIG. 6 cut along a line A1-A2.

FIG. 8 is a cross-sectional view of the display device shown in FIG. 6 cut along a line B1-B2.

FIG. 10 is a cross-sectional view of the display device shown in FIG. 9 cut along a line A1-A2.

FIG. 11 is a cross-sectional view of the display device shown in FIG. 9 cut along a line B1-B2.

FIG. 13 is a cross-sectional view of the display device shown in FIG. 12 cut along a line A1-A2.

FIG. 14 is a cross-sectional view of the display device shown in FIG. 12 cut along a line B1-B2.

FIG. 16 is a cross-sectional view of the display device shown in FIG. 15 cut along a line A1-A2.

FIG. 17 is a cross-sectional view of the display device shown in FIG. 15 cut along a line B1-B2.

FIG. 18 is a cross-sectional view of the display device shown in FIG. 15 cut along a line A1-A2.

FIG. 20 is a cross-sectional view of the display device shown in FIG. 19 cut along a line A1-A2.

FIG. 21 is a cross-sectional view of the display device shown in FIG. 19 cut along a line B1-B2.

FIG. 22, FIG. 23, and FIG. 24 are cross-sectional views of the display device shown in FIG. 19 cut along a line A1-A2.

FIG. 26 is a cross-sectional view of the display device shown in FIG. 25 cut along a line A1-A2.

FIG. 27 is a cross-sectional view of the display device shown in FIG. 25 cut along a line B1-B2.

FIG. 28, FIG. 29, and FIG. 30 are cross-sectional views of the display device shown in FIG. 25 cut along a line A1-A2.

FIG. 31 is a plan view of a plurality of pixel electrodes in a display area of the display device according to one or more embodiments.

FIG. 32 is a plan view of a conductive layer providing a capacitor of the display device according to one or more embodiments.

FIG. 33 is a cross-sectional view of the display device shown in FIG. 32 cut along a line C1-C2.

FIG. 34 is a block diagram of an electronic device according to an embodiment.

FIG. 35 to FIG. 37 are schematic diagrams of electronic devices according to various embodiments.

### DETAILED DESCRIPTION

One or more embodiments of the present disclosure will be described more fully hereinafter with reference to the accompanying drawings, so that those skilled in the art may implement one or more embodiments of the present disclosure. The present disclosure may be modified in one or more suitable ways, all without departing from the spirit or scope of the present disclosure and equivalents thereof.

To clearly describe the present disclosure, parts or portions that are irrelevant to the description are omitted, and identical or similar constituent elements throughout the specification are denoted by the same reference numerals.

In the drawings, a size and a thickness of each element are arbitrarily illustrated for ease of description, and the present disclosure is not necessarily limited to those illustrated in the drawings. In the drawings, the thicknesses of some layers and areas are exaggerated for clarity. In the drawings, for ease of description, the thicknesses of some layers and areas are exaggerated.

It should be understood that if (e.g., when) an element such as a layer, a film, a region, a plate, or the like is referred to as being “on” or “above” another element, it may be directly on the other element, or an intervening element may also be present. In contrast, if (e.g., when) an element is referred to as being “directly on” another element, there is no intervening element present. Further, in the specification, the word “on” or “above” means arranged on or below a referenced part, and does not necessarily mean arranged on the upper side of the referenced part based on a gravitational direction.

Spatially relative terms, such as “beneath,” “below,” “lower,” “lower side,” “under,” “above,” “upper,” “over,” “higher,” “upper side,” “side” (e.g., as in “sidewall”), and the like, may be utilized herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors utilized herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As utilized herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be utilized herein to describe various elements, components, regions, layers and/or sections, these elements, components, regions, layers and/or sections should not be limited by these terms. These terms do not correspond to a particular order, position, or superiority, and are utilized only utilized to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be utilized herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

Unless explicitly stated to the contrary, the word “comprise/have/include” and variations such as “comprises/has/includes” and “comprising/having/including” should be understood to imply the inclusion of stated elements but not the exclusion of any other elements.

Throughout the specification, the phrase “in a plan view” or “on a plane” may mean when an object portion is viewed from above and may mean a plane parallel to a first direction DR1 and a second direction DR2, and the phrase “in a cross-sectional view” or “on a cross-section” may mean when a cross-section taken by vertically cutting an object portion is viewed from the side and may mean a cross-section of the object portion cut in a third direction DR3.

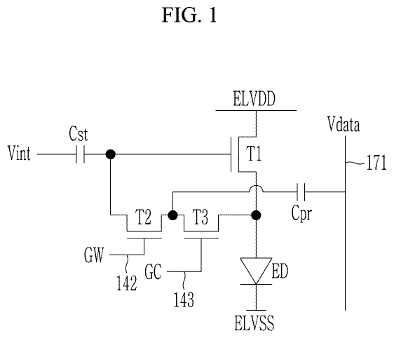

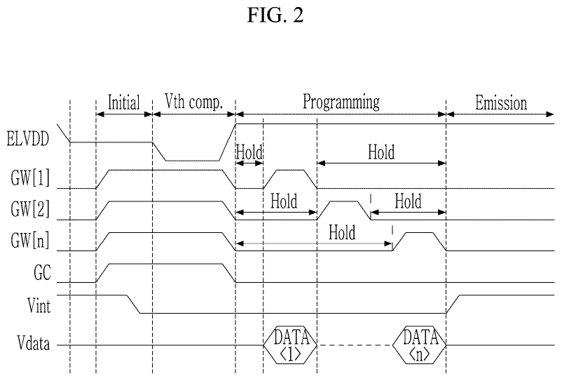

A pixel of a display device according to one or more embodiments will be described through FIG. 1 and FIG. 2.

FIG. 1 is an equivalent circuit diagram of one pixel of a display device according to one or more embodiments, and FIG. 2 is a timing diagram of a signal applied to the pixel shown in FIG. 1.

The pixel of the display device according to one or more embodiments may include a pixel circuit portion including a plurality of transistors and a plurality of capacitors, and a light-emitting element ED. The plurality of transistors may include a first transistor T1, a second transistor T2, and a third transistor T3, and the plurality of capacitors may include a storage capacitor Cst and a input capacitor Cpr. For example, the plurality of transistors (e.g., the first transistor T1, the second transistor T2, and/or the third transistor T3) may be n-type transistors, but the present disclosure is not limited thereto.

A voltage applied to a gate electrode of the first transistor T1 may change according to a data voltage Vdata, so that a driving current is transferred to the light-emitting element ED. A gate terminal of the first transistor T1 may be connected to the storage capacitor Cst, a driving voltage ELVDD (hereinafter also referred to as a first driving voltage) may be applied to a first terminal of the first transistor T1, and a second terminal of the first transistor T1 may be connected to an anode of the light-emitting element ED.

A second driving voltage ELVSS may be applied to a cathode of the light-emitting element ED.

The second transistor T2 and the third transistor T3 may be connected between the gate terminal and the second terminal of the first transistor T1. The input capacitor Cpr may be connected to an intermediate terminal, where the second transistor T2 and the third transistor T3 are connected. Hereinafter, the intermediate terminal between the second transistor T2 and the third transistor T3 to which the input capacitor Cpr is connected is referred to as a data voltage input terminal.

The second transistor T2 may be arranged between the gate terminal of the first transistor T1 and the data voltage input terminal. A first terminal of the second transistor T2 may be connected to the data voltage input terminal to receive the data voltage, and a second terminal of the second transistor T2 may be connected to the gate terminal of the first transistor T1 and the storage capacitor Cst. A gate terminal of the second transistor T2 may be connected to a scan line 142 to receive a scan signal GW.

The third transistor T3 may be arranged between the second terminal of the first transistor T1 and the data voltage input terminal. A first terminal of the third transistor T3 may be connected to the second terminal of the first transistor T1 and the anode of the light-emitting element ED, and a second terminal of the third transistor T3 may be connected to the data voltage input terminal to be connected to the first terminal of the second transistor T2. A gate terminal of the third transistor T3 may be connected to a control signal line 143 to receive a control signal GC.

The second transistor T2 may transfer the data voltage transferred through the input capacitor Cpr to the gate terminal of the first transistor T1, and the second transistor T2 and the third transistor T3 may operate together to initialize a voltage of the anode of the light-emitting element ED and a voltage of the gate terminal of the first transistor T1, and may allow a threshold voltage to be stored in the storage capacitor Cst.

The storage capacitor Cst may store and maintain the data voltage transferred to the gate terminal of the first transistor T1 through the second transistor T2. A first terminal of the storage capacitor Cst may be connected to the gate terminal of the first transistor T1 and the second terminal of the second transistor T2, and an initialization voltage Vint may be applied to a second terminal of the storage capacitor Cst.

The input capacitor Cpr may electrically connect a data line 171 to the data voltage input terminal. A first terminal of the input capacitor Cpr may be connected to the data voltage input terminal, and a second terminal of the input capacitor Cpr may be connected to the data line 171. A voltage of the data voltage input terminal may change according to a change in a voltage of the data line 171 by the input capacitor Cpr, and the second transistor T2 may be turned on to transfer the data voltage of the pixel to the gate terminal of the first transistor T1. In this case, because the data voltage Vdata passes through the input capacitor Cpr, an amount of change in a voltage occurring at the data voltage input terminal may be reduced compared with an amount of change in the data voltage Vdata occurring at the data line 171. In other words, a voltage value lower than the data voltage Vdata transferred by the data line 171 may be transferred to the data voltage input terminal. For ease of description, hereinafter, the term “data voltage” is utilized for a voltage transferred to the data voltage input terminal. However, for classification, the data voltage Vdata of the data line 171 and a data voltage of the data voltage input terminal may be separately named. The data voltage of the data voltage input terminal may also be referred to as the data voltage transferred through the input capacitor Cpr. The term “data voltage” may be utilized for ease of description if (e.g., when) the data voltage transferred to the data voltage input terminal is transferred to the gate terminal of the first transistor T1 and the storage capacitor Cst through the second transistor T2. For classification, the term “data voltage” may be expressed as the data voltage of the gate terminal of the first transistor T1 or the data voltage stored in the storage capacitor Cst.

An operation of the pixel circuit portion according to a signal applied to the pixel of the display device according to one or more embodiments will be described with reference to FIG. 1 and FIG. 2.

The pixel of the display device according to one or more embodiments may be operated in an initialization section Initial, a threshold voltage compensation section Vth Comp., a programming section Programming, and a light-emitting section Emission.

If (e.g., when) the first driving voltage ELVDD applied to the first terminal of the first transistor T1 is changed from a high voltage to a first low voltage, the light-emitting section Emission in which the light-emitting element ED emits light may end. In this case, the first low voltage may be less than or equal to a voltage value of the second driving voltage ELVSS applied to the cathode of the light-emitting element ED, so that an electric current does not flow in a forward direction in the light-emitting element ED. According to one or more embodiments, the first low voltage of the first driving voltage ELVDD may have a value slightly greater than the second driving voltage ELVSS, but even in this case, the first low voltage of the first driving voltage ELVDD may have a voltage value that prevents or reduces the likelihood of a voltage of the anode of the light-emitting element ED being higher than a voltage of the cathode so that the light-emitting section is terminated.

Thereafter, the initialization section Initial may start if (e.g., when) the scan signal GW applied to the scan line 142 and the control signal GC applied to the control signal line 143 are each changed to a high voltage (e.g., a turn-on voltage). The second transistor T2 and the third transistor T3 may be respectively turned on by the scan signal GW with the turn-on voltage and the control signal GC with the turn-on voltage, and the anode of the light-emitting element ED (e.g., the second terminal of the first transistor T1), the first terminal of the input capacitor Cpr, and the first terminal of the storage capacitor Cst (e.g., the gate terminal of the first transistor T1) may be connected to each other, so that they share an accumulated charge and their voltages are changed to the same voltage. The same voltage is referred to as a first connection voltage.

Then, the initialization voltage Vint may be changed to a low voltage during the initialization section Initial. As a result, a voltage value of the first terminal of the storage capacitor Cst that is the gate terminal of the first transistor T1 may be lowered. Thus, a voltage of the anode of the light-emitting element ED that is the second terminal of the first transistor T1 and a voltage of the first terminal of the input capacitor Cpr may also be lowered. In other words, if (e.g., when) the initialization voltage Vint is changed to the low voltage during the initialization section Initial, the first connection voltage may be changed to a second connection voltage lower than the first connection voltage. In this case, both the first connection voltage and the second connection voltage may concurrently be less than or equal to the voltage value of the second driving voltage ELVSS, so that a current does not flow in a forward direction in the light-emitting element ED and the light-emitting element ED does not emit light.

Thereafter, the threshold voltage compensation section Vth Comp. may start if (e.g., when) the first driving voltage ELVDD is changed from the first low voltage value to a second low voltage that has a lower voltage value than the first low voltage value. If (e.g., when) the first driving voltage ELVDD is changed to the second low voltage, a voltage of a gate terminal connected to the first terminal of the first transistor T1 by a parasitic capacitance that is the voltage of the first terminal of the storage capacitor Cst may also be lowered. However, the second low voltage value of the first driving voltage ELVDD may be sufficiently low, so that a voltage of the gate terminal of the first transistor T1 turns on the first transistor T1. In the threshold voltage compensation section, the scan signal GW with the turn-on voltage and the control signal GC with the turn-on voltage may be applied as in the initialization section, so that the second transistor T2 and the third transistor T3 are maintained in a turn-on state. Therefore, the first transistor T1 may have a diode-connection state where the gate terminal thereof and the second terminal thereof are connected to each other, and a voltage of the gate terminal may have a turn-on voltage value, so that a current flows from the second terminal to the first terminal thereof. The second terminal of the first transistor T1 may be connected to the gate terminal, so that an electric charge flows from the gate terminal to the first terminal and the voltage of the gate terminal is lowered. The voltage of the gate terminal of the first transistor T1 may continue to decrease, and then if (e.g., when) a difference between the voltage of the gate terminal and a voltage of the first terminal becomes a threshold voltage value of the first transistor T1, the first transistor T1 may be turned off. In this case, the voltage value of the gate terminal of the first transistor T1 may have a value greater than the second low voltage by the threshold voltage value of the first transistor T1, and the voltage value may be stored in the first terminal of the storage capacitor Cst. If (e.g., when) the second low voltage value is ELVDD_L and the threshold voltage value is Vth, a value stored in the first terminal of the storage capacitor Cst may be ELVDD_L+Vth. Because a value corresponding to the threshold voltage value of the first transistor T1 is stored in the storage capacitor Cst, this section may be referred to as the threshold voltage compensation section. Here, because both the second transistor T2 and the third transistor T3 are concurrently turned on, the voltage of the first terminal of the storage capacitor Cst and the voltage of the first terminal of the input capacitor Cpr may have the same value, and the voltage of the anode of the light-emitting element ED, the voltage of the first terminal of the storage capacitor Cst, and the voltage of the first terminal of the input capacitor Cpr may also have the same value.

In the threshold voltage compensation section, voltage values of the gate terminal and the second terminal of the first transistor T1 may be changed to values lower than the first connection voltage and the second connection voltage of the initialization section, so that they all are lower than the voltage value of the second driving voltage ELVSS. As a result, a current may not flow in a forward direction in the light-emitting element ED, and the light-emitting element ED may not emit light.

Thereafter, the scan signal GW applied to the scan line 142 and the control signal GC applied to the control signal line 143 may each be changed to a low voltage that is a turn-off voltage, and the first driving voltage ELVDD may be changed from the second low voltage to the high voltage. If (e.g., when) the first driving voltage ELVDD is changed to the high voltage, the voltage of the gate terminal of the first transistor T1 may increase. In other words, a value previously stored in the first terminal of the storage capacitor Cst is ELVDD_L+Vth, and if the high voltage value of the first driving voltage ELVDD is ELVDD_H, a value stored in the first terminal of the storage capacitor Cst may be ELVDD_H+Vth−a. A voltage change value of the gate terminal may be less than a voltage change value of the first terminal of the first transistor T1. The value of “a” may represent a degree to which the voltage change value of the gate terminal is less than the voltage change value of the first terminal of the first transistor T1. As a result, a voltage difference between the first terminal and the gate terminal of the first transistor T1 may be lower than the threshold voltage (Vth), so that the first transistor T1 does not output a current. Because the second transistor T2 and the third transistor T3 are in a turn-off state, an increase in the voltage of the gate terminal of the first transistor T1 may not affect the anode of the light-emitting element ED. Therefore, the light-emitting element ED may still not emit light.

Thereafter, the programming section Programming, in which a turn-on voltage is applied to the scan line 142, may start. In the programming section Programming, the second transistor T2 may be turned on by the scan signal GW with the turn-on voltage applied to the scan line 142, and the data voltage of the data voltage input terminal may be transferred to the first terminal of the storage capacitor Cst to be stored in the first terminal of the storage capacitor Cst. The data voltage of the data voltage input terminal may be a voltage transferred from the data line 171 through the input capacitor Cpr, and may have a lower voltage value than the data voltage Vdata transferred by the data line 171. The voltage of the first terminal of the storage capacitor Cst before the programming section proceeds is ELVDD_H+Vth−a, and if (e.g., when) the data voltage of the data voltage input terminal is Vdata−b (where b indicates that a voltage that is lower than a voltage transferred by the data line 171 is caused), the voltage of the first terminal of the storage capacitor Cst after the programming section proceeds may be ELVDD_H+Vth−a+Vdata−b. In this case, a voltage difference between the first terminal and the gate terminal of the first transistor T1 may still be set to be less than the threshold voltage (Vth) due to the values of “a” and “b.”

Therefore, the first transistor T1 may not generate an output current.

In FIG. 2, a holding section Hold may be included in the programming section Programming, and the holding section Hold may be a section before and after the scan signal GW applies the turn-on voltage, and may have a different holding section Hold for each scan line 142. The holding section Hold may be a section where voltages of the storage capacitor Cst and every other terminal are maintained.

If (e.g., when) the data voltage of the data voltage input terminal is stored in the first terminal of the storage capacitor Cst of all pixels of the display device, the light-emitting element ED may emit light if (e.g., when) the initialization voltage Vint is changed from a low voltage to a high voltage. This section may be referred to as the light-emitting section Emission.

If (e.g., when) the initialization voltage Vint is changed to the high voltage, the voltage of the first terminal of the storage capacitor Cst may also increase, and a voltage difference between the first terminal and the gate terminal of the first transistor T1 may be greater than the threshold voltage (Vth), so that the first transistor T1 emits an output current. A current output from the first transistor T1 may be transferred to the anode of the light-emitting element ED, and a degree to which the light-emitting element ED emits light may be changed according to a size of the current.

In this case, the voltage of the gate terminal of the first transistor T1 may be ELVDD_H+Vth−a+Vdata−b+c, and here, c may represent a voltage value increased as the initialization voltage Vint is changed to the high voltage. Here, if (e.g., when) the value of “c” is set to a value that offsets the value of “a” and the value of “b,” a final voltage of the gate terminal of the first transistor T1 may become ELVDD_H+Vth+Vdata. In this case, because the first terminal of the first transistor T1 has the voltage value of ELVDD_H, the voltage difference between the first terminal and the gate terminal of the first transistor T1 may be Vth+Vdata, the value of Vth may be utilized to turn on the first transistor T1, and only the remaining Vdata may be utilized to determine the output current of the first transistor T1. As a result, in the pixel, the output current of the first transistor T1 may be determined according to the data voltage Vdata applied to the data line 171.

Even if the value of the threshold voltage (Vth) is different for each first transistor T1, the value of the threshold voltage (Vth) may already be included in the gate terminal of the first transistor T1 to be compensated, and the output current may be determined by the remaining data voltage Vdata, and thus, it is suitable not to consider the threshold voltage of each first transistor T1. In addition, even if the threshold voltage of each first transistor T1 is different, display quality may not be degraded by emitting the same luminance for the same data voltage.

In the light-emitting section Emission, all pixels may emit light at one time for the same time. However, the present disclosure is not limited thereto, and according to one or more embodiments, some pixels may concurrently or substantially simultaneously emit light.

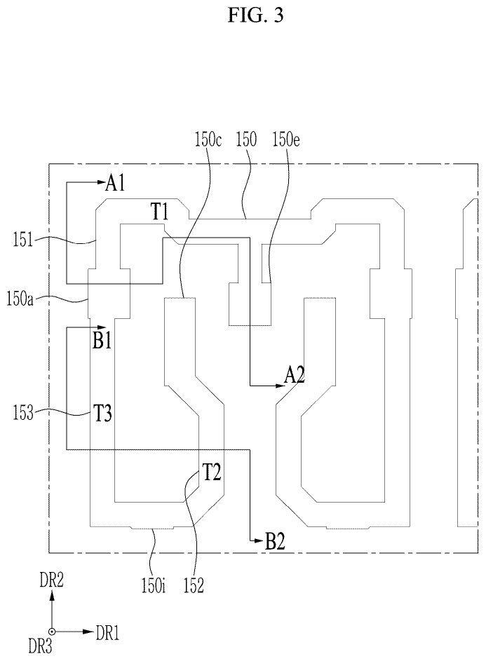

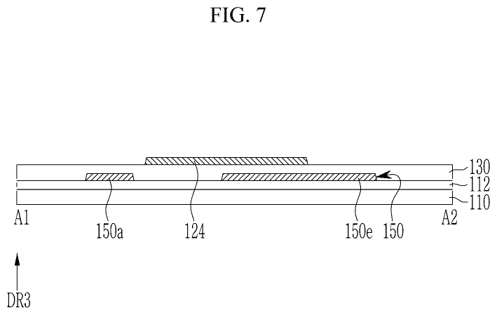

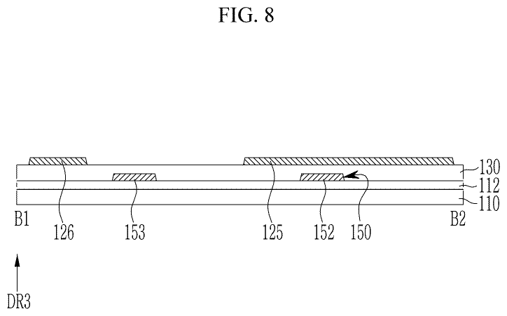

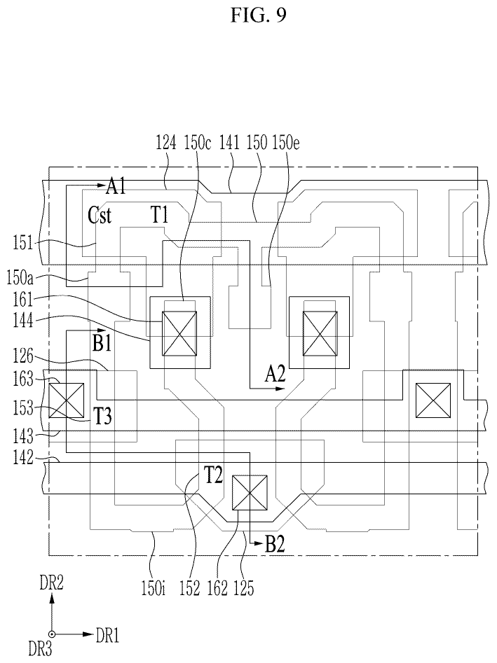

A structure of the display device according to one or more embodiments will be described with reference to FIGS. 3 to 31 together with FIG. 1. For convenience of description and understanding, an order of layers stacked on a substrate will be described. FIG. 3, FIG. 6, FIG. 9, FIG. 12, FIG. 15, FIG. 19, and FIG. 25 each shows a pixel circuit portion of two adjacent pixels among a plurality of pixels included in the display device, according to one or more embodiments. The pixel circuit portions of the two pixels adjacent to each other in the first direction DR1 may be symmetrical to each other in the first direction DR1.

FIGS. 3 to 5 each shows a semiconductor pattern 150 arranged above a substrate included in the display device, according to one or more embodiments.

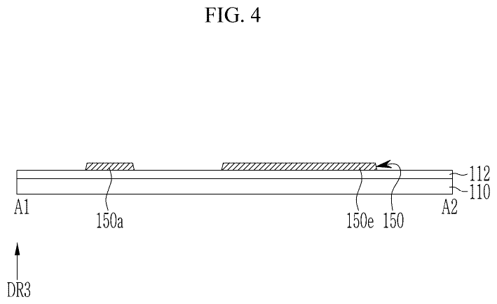

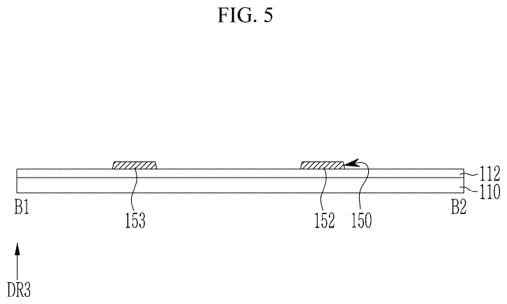

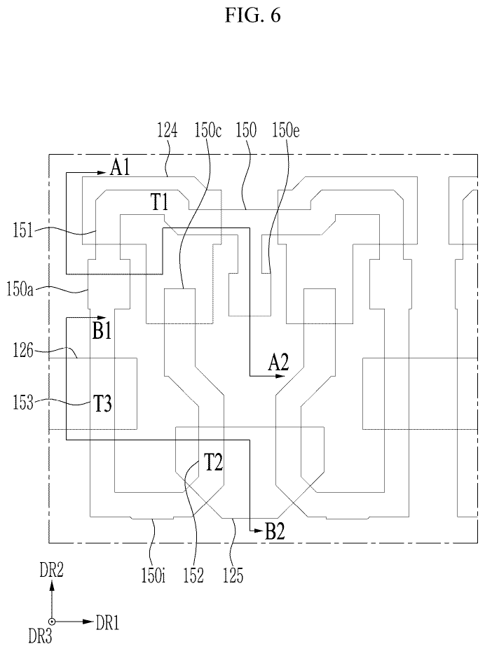

Referring to FIG. 4 and FIG. 5, the display device according to one or more embodiments may include the substrate 110. The substrate 110 may include an insulating material, and may include glass, plastic, and/or the like. The semiconductor pattern 150 may be arranged above the substrate 110. The semiconductor pattern 150 may include a semiconductor material, such as amorphous silicon, polycrystalline silicon, an oxide semiconductor, and/or the like.

Referring to FIG. 3, semiconductor patterns 150 arranged at two pixels adjacent to each other in the first direction DR1 may be connected to each other. The semiconductor pattern 150 may include a first driving voltage input semiconductor 150e arranged at a boundary of the two pixels adjacent to each other in the first direction DR1, a semiconductor 151 for the first transistor T1, an anode connection semiconductor 150a, a semiconductor 153 for the third transistor T3, a data voltage input semiconductor 150i connected to the first terminal of the input capacitor Cpr, a semiconductor 152 for the second transistor T2, and/or a storage capacitor connection semiconductor 150c connected to the first terminal of the storage capacitor Cst.

FIGS. 6 to 8 additionally each shows a first conductive layer arranged above the semiconductor pattern 150.

Referring to FIGS. 6 to 8, a first insulating layer 130 may be arranged on the semiconductor pattern 150. The first insulating layer 130 may include an inorganic insulating material, such as silicon oxide (SiOₓ), silicon nitride (SiNₓ), and/or the like. A thickness in the third direction DR3 of the first insulating layer 130 may be approximately 1000 angstroms to approximately 2000 angstroms, but the present disclosure is not limited thereto. The third direction DR3 may be a direction substantially perpendicular to the first direction DR1 and the second direction DR2.

The first conductive layer may be arranged on the first insulating layer 130. The first conductive layer may include a first gate electrode 124, a second gate electrode 125, and a third gate electrode 126. The first gate electrode 124 may constitute the gate terminal of the first transistor T1, and may also serve as the first terminal of the storage capacitor Cst. The first gate electrode 124 may overlap the semiconductor 151 for the first transistor T1 to define a channel area of the first transistor T1. The second gate electrode 125 may constitute the gate terminal of the second transistor T2, and may overlap semiconductors 152 for two second transistors T2 adjacent to each other in the first direction DR1 to define a channel area of the second transistor T2. The third gate electrode 126 may constitute the gate terminal of the third transistor T3, and may overlap semiconductors 152 for two semiconductor patterns 150 adjacent to each other in the first direction DR1 to define a channel area of the third transistor T3.

Each of the first gate electrode 124, the second gate electrode 125, and/or the third gate electrode 126 may not have a linear structure elongated in the first direction DR1, and may have an have an island shape. A width in the first direction DR1 of each of the first gate electrode 124, the second gate electrode 125, and the third gate electrode 126 may not be greater than a width in the first direction DR1 of each pixel circuit portion.

A portion of the semiconductor pattern 150 that overlaps the first gate electrode 124, the second gate electrode 125, and the third gate electrode 126 on a plane may provide (e.g., form) the channel area of each of the transistors (e.g., the first transistor T1, the second transistor T2, and the third transistor T3), and a portion of the semiconductor pattern 150 that does not overlap the first gate electrode 124, the second gate electrode 125, and the third gate electrode 126 on a plane (e.g., that is spaced from the first gate electrode 124, the second gate electrode 125, and the third gate electrode 126 in plan view) may be provided as a conductive area by a doping process. The conductive area of the semiconductor pattern 150 may include the first driving voltage input semiconductor 150e, the anode connection semiconductor 150a, the data voltage input semiconductor 150i, the storage capacitor connection semiconductor 150c, and/or the like.

The first conductive layer may include a metal and/or a metal alloy, such as copper (Cu), molybdenum (Mo), aluminum (Al), silver (Ag), chromium (Cr), tantalum (Ta), titanium (Ti), and/or the like, and may be provided as a single layer or multiple layers.

FIGS. 9 to 11 additionally each shows a second conductive layer arranged on the first conductive layer.

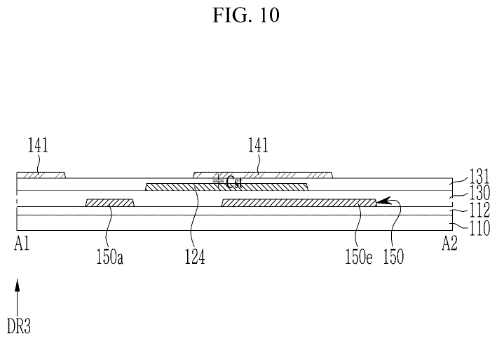

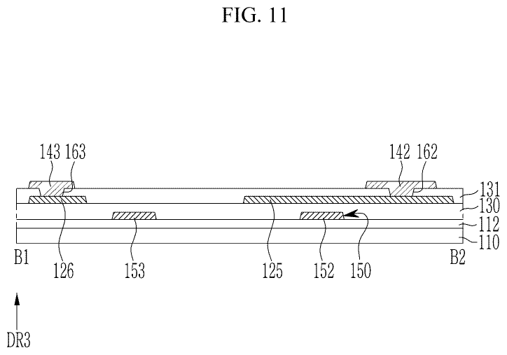

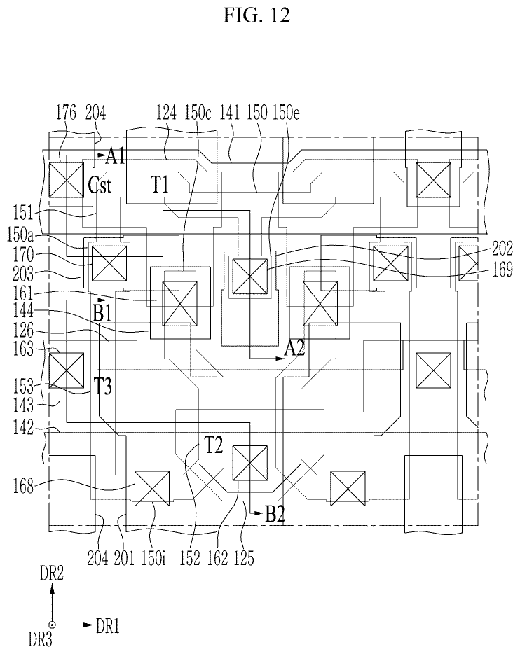

Referring to FIG. 10 and FIG. 11, the second insulating layer 131 may be arranged on the first conductive layer. The second insulating layer 131 may include an inorganic insulating material, such as silicon oxide (SiOₓ), silicon nitride (SiNₓ), and/or the like. A thickness in the third direction DR3 of the second insulating layer 131 may be approximately 1000 angstroms to approximately 2000 angstroms, but the present disclosure is not limited thereto.

The second conductive layer may be arranged on the second insulating layer 131. The second conductive layer may include a horizontal initialization voltage line 141, the scan line 142, the control signal line 143, and a connection member 144.

Referring to FIG. 9, the horizontal initialization voltage line 141 may be elongated in the first direction DR1 to intersect pixel circuit portions of the plurality of pixels. Referring to FIG. 9 and FIG. 10, the horizontal initialization voltage line 141 may overlap the first gate electrode 124 with the second insulating layer 131 therebetween (e.g., the second insulating layer 131 is between the horizontal initialization voltage line 141 and the first gate electrode 124) to provide the storage capacitor Cst.

Each of the scan line 142 and the control signal line 143 may be elongated in the first direction DR1 to intersect pixel circuit portions of the plurality of pixels. The scan line 142 may overlap the second gate electrode 125 on a plane, and may be electrically connected to the second gate electrode 125 through an opening 162 of the second insulating layer 131. The control signal line 143 may overlap the third gate electrode 126 on a plane, and may be electrically connected to the third gate electrode 126 through an opening 163.

The connection member 144 may have an island shape provided by being limited to each pixel. The connection member 144 may be electrically connected to the storage capacitor connection semiconductor 150c and the first gate electrode 124 through an opening 161 of the second insulating layer 131. The storage capacitor connection semiconductor 150c and the first gate electrode 124 may be electrically connected to each other through the connection member 144. The connection member 144 and the opening 161 may have a side contact structure.

The second conductive layer may include a metal and/or a metal alloy, such as copper (Cu), molybdenum (Mo), aluminum (Al), silver (Ag), chromium (Cr), tantalum (Ta), titanium (Ti), and/or the like, and may be provided as a single layer or multiple layers.

FIGS. 12 to 14 additionally each shows a third conductive layer arranged on the second conductive layer.

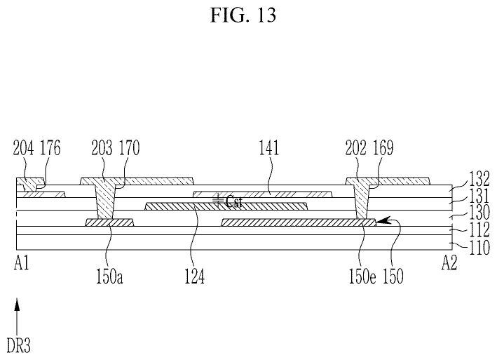

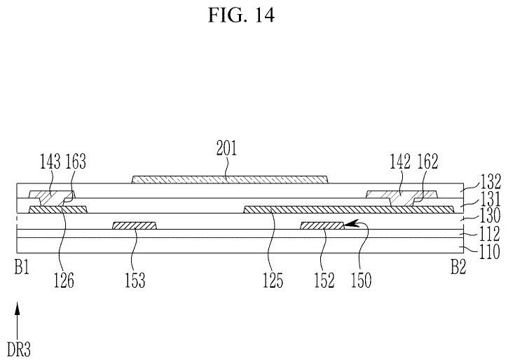

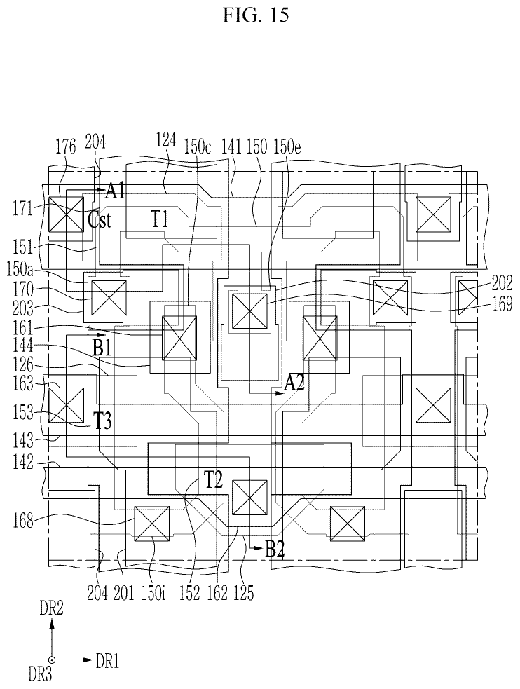

Referring to FIG. 13 and FIG. 14, the third insulating layer 132 may be arranged on the second conductive layer. The third insulating layer 132 may include an inorganic insulating material, such as silicon oxide (SiOₓ), silicon nitride (SiNₓ), and/or the like. A thickness in the third direction DR3 of the third insulating layer 132 may be approximately 2000 angstroms to approximately 6000 angstroms, but the present disclosure is not limited thereto. The thickness in the third direction DR3 of the third insulating layer 132 may be greater than the thickness in the third direction DR3 of the first insulating layer 130 or the second insulating layer 131. The third insulating layer 132 may have a structure with two or more layers. For example, the third insulating layer 132 may include a layer including silicon oxide and a layer including silicon nitride. For example, a thickness in the third direction DR3 of each of the layer including silicon oxide and the layer including silicon nitride of the third insulating layer 132 may be approximately 2000 angstroms.

The third conductive layer may be arranged on the third insulating layer 132. The third conductive layer may include a first electrode 201 for the input capacitor, and a plurality of connection members 202, 203, and 204.

The first electrode 201 for the input capacitor may be provided one by one for each pixel, and may have an island shape. The first electrode 201 for the input capacitor may be electrically connected to the data voltage input semiconductor 150i through an opening 168 of the first insulating layer 130, the second insulating layer 131, and the third insulating layer 132. The first electrode 201 for the input capacitor may provide the first terminal of the input capacitor Cpr. A planar area of the first electrode 201 for the input capacitor may be greater than a planar area of each of the plurality of connection members 202, 203, and 204.

The connection member 202 may have an island shape arranged to be confined between adjacent pixels. The connection member 202 may overlap the first driving voltage input semiconductor 150e on a plane, and may be electrically connected to the first driving voltage input semiconductor 150e through an opening 169 of the first insulating layer 130, the second insulating layer 131, and the third insulating layer 132. A length in the second direction DR2 of the connection member 202 may be greater than a length in the first direction DR1.

The connection member 203 may have an island shape arranged to be limited to each pixel. The connection member 203 may overlap the anode connection semiconductor 150a on a plane, and may be electrically connected to the anode connection semiconductor 150a through an opening 170 of the first insulating layer 130, the second insulating layer 131, and the third insulating layer 132. A length in the first direction DR1 of the connection member 203 may be greater than a length in the second direction DR2.

The connection member 204 may have an island shape arranged to be confined between adjacent pixels. The connection member 204 may overlap the horizontal initialization voltage line 141 on a plane, and may be electrically connected to the horizontal initialization voltage line 141 through an opening 176 of the third insulating layer 132. A length in the second direction DR2 of the connection member 204 may be greater than a length in the first direction DR1 thereof.

The third conductive layer may be provided as a single layer or multiple layers, and may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu). For example, the third conductive layer may be formed of a triple layer such as Ti/Al/Ti (e.g., a layer of Ti, a layer of Al, and a layer of Ti).

FIGS. 15 to 18 additionally each shows a fourth conductive layer arranged on the third conductive layer.

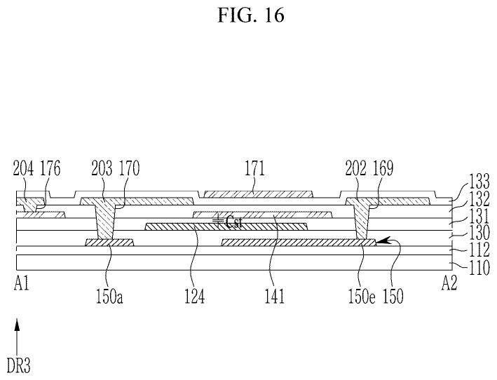

Referring to FIGS. 16 to 18, the fourth insulating layer 133 may be arranged on the third conductive layer. The fourth insulating layer 133 may include an inorganic insulating material, such as silicon oxide (SiOₓ), silicon nitride (SiNₓ), and/or the like. A thickness in the third direction DR3 of the fourth insulating layer 133 may be approximately 1000 angstroms to approximately 2000 angstroms, but the present disclosure is not limited thereto.

The fourth conductive layer may be arranged on the fourth insulating layer 133. The fourth conductive layer may include a voltage line such as the data line 171 and/or the like. Referring to FIG. 15, the data line 171 may be elongated in the second direction DR2 to intersect pixel circuit portions of the plurality of pixels. The data line 171 may include at least one extension portion corresponding to each pixel. The extension portion of the data line 171 may provide the second terminal of the input capacitor Cpr.

Two data lines 171 may be provided adjacent to one semiconductor pattern 150 in the first direction DR1. Two data lines 171 overlapping one semiconductor pattern 150 on a plane may be symmetrical with respect to a vertical center line of the semiconductor pattern 150.

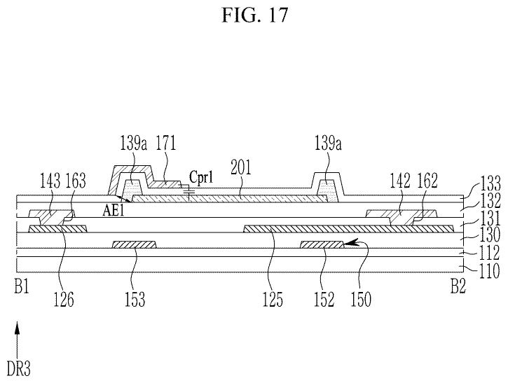

Referring to FIG. 15 and FIG. 17, the data line 171 may overlap the first electrode 201 for the input capacitor with the fourth insulating layer 133 therebetween (e.g., the fourth insulating layer 133 is between the data line 171 and the first electrode 201) to provide a first input capacitor Cpr1. The first input capacitor Cpr1 may be included in the input capacitor Cpr.

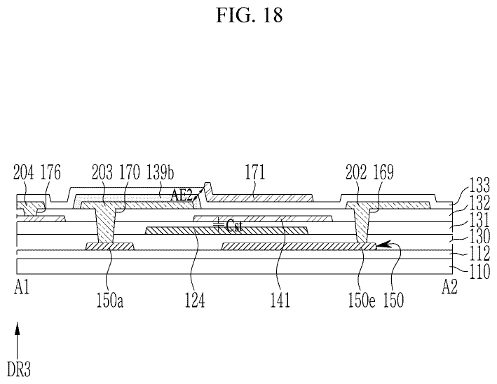

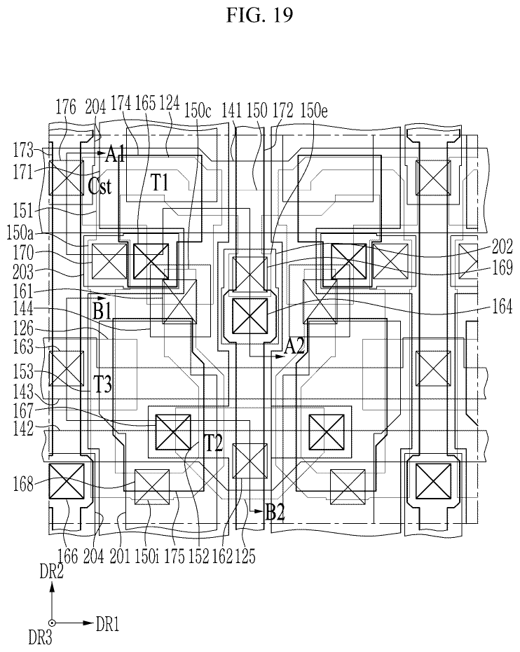

Referring to FIG. 17 and FIG. 18, an insulating pattern 139a or 139b may be arranged between the third conductive layer and the fourth insulating layer 133. The insulating pattern 139a or 139b may overlap at least a portion of the third conductive layer, and, for example, may overlap and cover at least a portion of an edge of the third conductive layer on a plane. The insulating pattern 139a or 139b may include an organic insulating material, such as a general-purpose polymer (e.g., polymethylmethacrylate (PMMA) or polystyrene (PS)), a polymer derivative having a phenol-based group, an acryl-based polymer, an imide-based polymer, polyimide, a siloxane-based polymer, and/or the like.

The insulating pattern 139a or 139b may contact an upper surface and a side surface of the third conductive layer that overlap the insulating pattern 139a or 139b on a plane. The fourth insulating layer 133 on the insulating pattern 139a or 139b and the third conductive layer may contact the upper surface and the side surface of the insulating pattern 139a or 139b, and the third conductive layer that is not covered by the insulating pattern 139a or 139b. The fourth insulating layer 133 may contact the insulating pattern 139a or 139b.

In a manufacturing method of the display device according to one or more embodiments, after the organic insulating material for the insulating pattern 139a or 139b is stacked, the insulating pattern 139a or 139b may be provided by patterning utilizing a photo process and/or the like, and then the fourth insulating layer 133 may be stacked after a gas that may be inside the insulating pattern 139a or 139b is exhausted through annealing.

For example, referring to FIG. 17, the insulating pattern 139a may overlap and cover at least a portion of an edge of the first electrode 201 for the input capacitor of the third conductive layer on a plane. The insulating pattern 139a may extend along the edge of the first electrode 201 for the input capacitor on a plane to have a closed curve band shape. The insulating pattern 139a may have a width sufficient to cover the edge of the first electrode 201 for the input capacitor. Because the first electrode 201 for the input capacitor is one terminal of the first input capacitor Cpr1, to secure a sufficient capacity of the first input capacitor Cpr1, the insulating pattern 139a may cover only the edge of the first electrode 201 for the input capacitor and not a central portion of the first electrode 201 for the input capacitor, and may not overlap the central portion of the first electrode 201 for the input capacitor on a plane (e.g., may be spaced from the central portion of the first electrode 201 for the input capacitor in plan view).

Referring to FIG. 18, the insulating pattern 139b may overlap and cover at least some edges of the plurality of connection members 202, 203, and 204 on a plane. The insulating pattern 139b may extend along the edge of the connection members 202, 203, and/or 204, to have a closed curve band shape similarly to the insulating pattern 139a, or may overlap and cover the entirety of the connection member 202, 203, and/or 204 including the edges of the connection member 202, 203, and/or 204 as shown in FIG. 18. Because the connection members 202, 203, and 204 do not provide capacitors that may affect display quality of an image together with another conductive layer, the insulating pattern 139b may cover upper surfaces of the connection members 202, 203, and 204.

As shown in FIG. 16, the insulating pattern 139b may not be provided.

A thickness in the third direction DR3 of the insulating pattern 139a or 139b may be approximately 1 micrometer to approximately 1.5 micrometer, but the present disclosure is not limited thereto.

The fourth conductive layer may be provided of multiple layers, and may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu). For example, the fourth conductive layer may be formed of a triple layer such as Ti/Al/Ti (e.g., a layer of Ti, a layer of Al, and a layer of Ti).

In the manufacturing method of the display device according to one or more embodiments, the third conductive layer may be patterned by a photo-etching process and/or the like after conductive materials are stacked, and if (e.g., when) the third conductive layer is provided of multiple layers with different metals, the third conductive layer may have a tip shape, in which an upper layer of the multiple layers protrudes more laterally than another layer depending on an etching ratio. For example, if (e.g., when) the third conductive layer is provided of the triple layer of Ti/Al/Ti (e.g., a layer of Ti, a layer of Al, and a layer of Ti), an etching rate of aluminum (Al) of an intermediate layer may be higher than an etching rate of titanium (Ti), so that the third conductive layer has a tip shape, in which an upper layer including titanium (Ti) protrudes more laterally than the intermediate layer. If (e.g., when) the insulating pattern 139a or 139b does not cover an edge of the third conductive layer and the fourth insulating layer 133 is directly stacked, the fourth insulating layer 133 including the inorganic insulating material may have a defect, such as a crack and/or the like in the fourth insulating layer 133 due to the upper layer of the third conductive layer protruding in the tip shape. Then, the first electrode 201 for the input capacitor of the third conductive layer that provides a capacitor (e.g., the input capacitor Cpr) that affects operation of the pixel circuit and display quality of the display device may be short-circuited with a conductive layer provided thereon (e.g., the conductive layer is on the first electrode 201), causing leakage to occur.

According to one or more embodiments, the multiple layers of the third conductive layer may include a first layer including a first metal and a second layer including a second metal different from the first metal and arranged below the first layer, and an etching rate of the first layer may be lower than an etching rate of the second layer, so that the first layer provides a tip shape at an edge of the third conductive layer. For example, the first layer may include titanium (Ti), and the second layer may include aluminum (Al).

However, because the insulating pattern 139a or 139b covers the edge of the third conductive layer, the upper layer of the third conductive layer protruding in the tip shape may be covered by a relatively thick insulating pattern 139a or 139b including the organic insulating material, so that the fourth insulating layer 133 is protected. Accordingly, the leakage caused by the short circuit between the first electrode 201 for the input capacitor of the third conductive layer that provides the capacitor (e.g., the input capacitor Cpr) that affects the operation of the pixel circuit and display quality and the conductive layer provided thereon may be prevented or reduced. As shown in FIG. 17, even if the edge of the first electrode 201 for the input capacitor covered with the insulating pattern 139a protrudes in a tip shape, a short circuit and leakage between the edge of the first electrode 201 and the data line 171 of the fourth conductive layer adjacent to and arranged above the edge of the first electrode 201 may be prevented or reduced. An interval between the edge of the first electrode 201 and the data line 171 of the fourth conductive layer may be indicated by arrow AE1. As shown in FIG. 18, even if the edge of the connection members 202, 203, and 204 covered with the insulating pattern 139b protrude in a tip shape, a short circuit and leakage between the edge of the connection members 202, 203, and 204 and the data line 171 of the fourth conductive layer adjacent to and arranged above the edge of the connection members 202, 203, and 204 may be prevented or reduced. An interval between the edge of the connection members 202, 203, and 204 and the data line 171 of the fourth conductive layer may be indicated by arrow AE2.

FIGS. 19 to 24 additionally each shows a fifth conductive layer arranged on the fourth conductive layer.

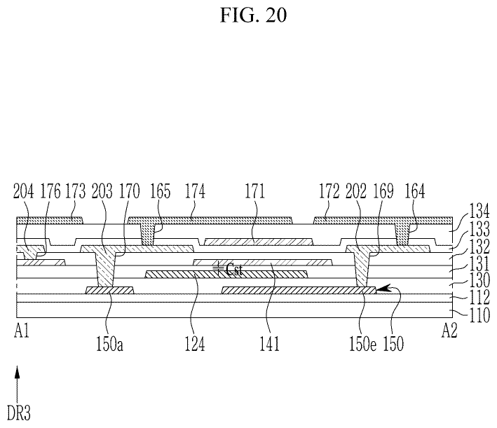

Referring to FIGS. 20 to 24, the fifth insulating layer 134 may be arranged on the fourth conductive layer. The fifth insulating layer 134 may include an inorganic insulating material, such as silicon oxide (SiOₓ), silicon nitride (SiNₓ), and/or the like. A thickness in the third direction DR3 of the fifth insulating layer 134 may be approximately 1000 angstroms to approximately 2000 angstroms, but the present disclosure is not limited thereto.

The fifth conductive layer may be arranged on the fifth insulating layer 134. The fifth conductive layer may include a driving voltage line 172, a vertical initialization voltage line 173, an anode connection member 174, and a second electrode 175 for the input capacitor.

The driving voltage line 172 may be elongated in the second direction DR2, and may extend along pixel circuit portions of the plurality of pixels. The driving voltage line 172 may transfer the first driving voltage ELVDD. The driving voltage line 172 may be electrically connected to the connection member 202 through an opening 164 of the fourth insulating layer 133 and the fifth insulating layer 134, and may be electrically connected to the first driving voltage input semiconductor 150e through the connection member 202. Accordingly, the first driving voltage ELVDD may be transferred to the first driving voltage input semiconductor 150e of the semiconductor pattern 150. Because the driving voltage line 172 is provided one by one for each semiconductor pattern 150, two pixel columns may have a structure, in which one driving voltage line 172 is shared.

The vertical initialization voltage line 173 may be elongated in the second direction DR2, and may extend along pixel circuit portions of the plurality of pixels. The vertical initialization voltage line 173 may transfer the initialization voltage Vint. The vertical initialization voltage line 173 may be electrically connected to the connection member 204 through an opening 166 of the fourth insulating layer 133 and the fifth insulating layer 134, and may be electrically connected to the horizontal initialization voltage line 141 through the connection member 204. Accordingly, the initialization voltage Vint may be connected in the first direction DR1 and the second direction DR2, so that the voltage is transferred in a mesh shape, and a uniform initialization voltage Vint may be transferred to the pixel circuit portions of the plurality of pixels arranged on a plane.

The driving voltage line 172 and the vertical initialization voltage line 173 may be provided on a conductive layer different from the data line 171, so that the data line 171 is provided to have a sufficiently wide width. Accordingly, the input capacitor Cpr may also have a sufficiently large capacity, so that the data voltage is transferred to the pixel circuit portion with high efficiency.

The anode connection member 174 may have an island shape provided by being limited to each pixel. The anode connection member 174 may be electrically connected to the connection member 203 through an opening 165 of the fourth insulating layer 133 and the fifth insulating layer 134, and may be electrically connected to the anode connection semiconductor 150a through the connection member 203.

The second electrode 175 for the input capacitor may be provided one by one for each pixel, and may have an island shape. The second electrode 175 for the input capacitor may overlap the data line 171 with the fifth insulating layer 134 therebetween (e.g., the fifth insulating layer 134 is between the second electrode 175 and the data line 171) to provide a second input capacitor Cpr2. The second input capacitor Cpr2 may be included in the input capacitor Cpr. The second electrode 175 for the input capacitor may be electrically connected to the first electrode 201 for the input capacitor through an opening 167 of the fourth insulating layer 133 and the fifth insulating layer 134. Accordingly, the second electrode 175 for the input capacitor may provide the first terminal of the input capacitor Cpr together with the first electrode 201 for the input capacitor. The first input capacitor Cpr1 and the second input capacitor Cpr2 may be electrically connected in parallel to provide one input capacitor Cpr of the pixel, and may increase a capacity of the input capacitor Cpr through parallel connection.

The first electrode 201 for the input capacitor may be electrically connected to the data voltage input semiconductor 150i through the opening 168, so that the data voltage transferred by coupling through the input capacitor Cpr is transferred to the data voltage input semiconductor 150i between the second transistor T2 and the third transistor T3.

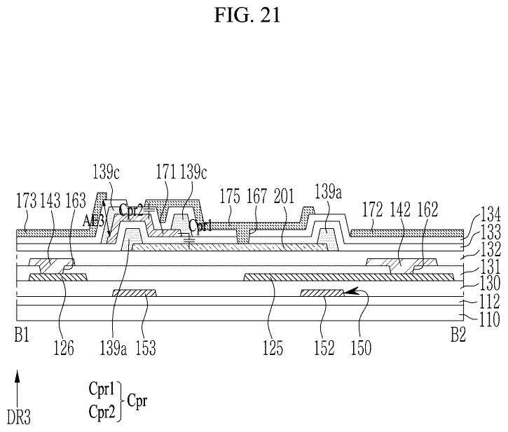

Referring to FIGS. 21 to 24, an insulating pattern 139c or 139d may be arranged between the fourth conductive layer and the fifth insulating layer 134. The insulating pattern 139c or 139d may overlap at least a portion of the fourth conductive layer, and for example, may overlap and cover at least a portion of an edge of the fourth conductive layer on a plane. The insulating pattern 139c or 139d may include an organic insulating material, such as a general-purpose polymer (e.g., polymethyl methacrylate (PMMA) or polystyrene (PS)), a polymer derivative having a phenol-based group, an acryl-based polymer, an imide-based polymer, polyimide, a siloxane-based polymer, and/or the like.

The insulating pattern 139c or 139d may contact an upper surface and a side surface of the planarly overlapping fourth conductive layer. The fifth insulating layer 134 on the insulating pattern 139c or 139d and the fourth conductive layer may contact the upper surface and side surface of the insulating pattern 139c or 139d, and the fourth conductive layer that is not covered by the insulating pattern 139c or 139d. The fifth insulating layer 134 may be in contact with the insulating pattern 139c or 139d.

In a manufacturing method of the display device according to one or more embodiments, after the organic insulating material for the insulating pattern 139c or 139d is stacked, the insulating pattern 139c or 139d may be provided by patterning utilizing a photo process and/or the like, and then the fifth insulating layer 134 may be stacked after gas that may be inside the insulating pattern 139c or 139d is exhausted through annealing.

For example, referring to FIG. 21, the insulating pattern 139c may overlap and cover planarly at least a portion of an edge of the data line 171 of the third conductive layer. The insulating pattern 139c may extend along the edge of the in-plane data line 171 to provide a closed curve band shape, and may extend only along an edge of a portion that provides the second input capacitor Cpr2. For example, a portion that planarly overlaps the second electrode 175 for the input capacitor. The insulating pattern 139c may have a width sufficient to cover the edge of the data line 171. Because the data line 171 is one terminal of the second input capacitor Cpr2, to secure sufficient capacity of the second input capacitor Cpr2, the insulating pattern 139c may cover only the edge of the data line 171, may not cover a central portion of the data line 171, and may not planarly overlap the central portion of the data line 171.

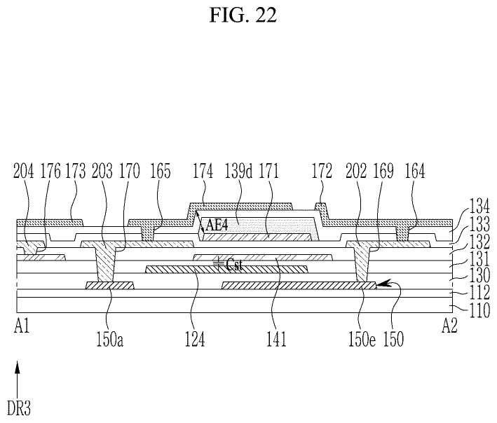

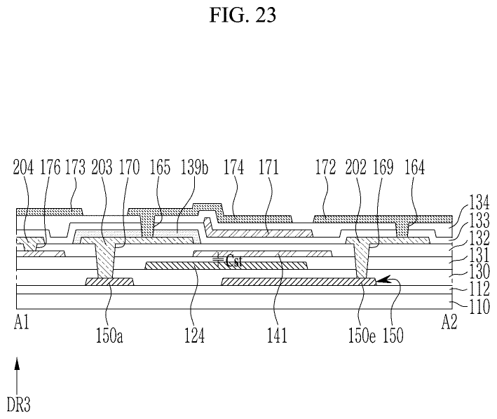

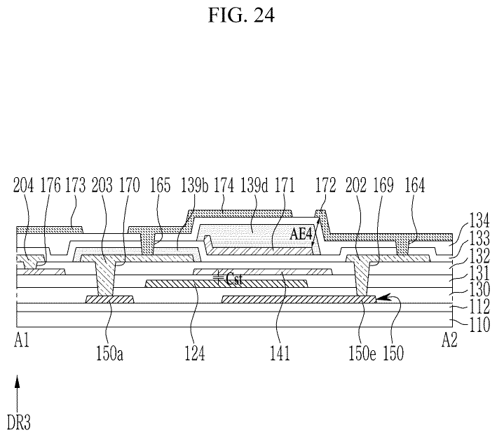

Referring to FIG. 22 and FIG. 24, the insulating pattern 139d may planarly overlap and cover an edge of a portion of the data line 171 that does not provide a capacitor such as the input capacitor Cpr. Similar to the insulating pattern 139c, the insulating pattern 139d may extend along the edge of the data line 171 to have a band shape, and may overlap and cover an entire data line 171 including the edge of the data line 171 as shown in FIG. 22. The insulating pattern 139d may cover the upper surface of the portion of the data line 171 because the portion of the data line 171 not providing the capacitor, such as the input capacitor Cpr does not provide a capacitor affecting the quality of image display together with another conductive layer.

FIG. 20 shows a structure in which the insulating pattern 139d is not provided in one or more embodiments, in which the insulating pattern 139b is not provided above the connection member 202, 203, or 204 of the third conductive layer. FIG. 22 shows a structure in which the insulating pattern 139d is provided in one or more embodiments, in which the insulating pattern 139b is not provided above the connection member 202, 203, or 204 of the third conductive layer.

FIG. 23 shows a structure in which the insulating pattern 139d is not provided in one or more embodiments, in which the insulating pattern 139b is provided on the connection member 202, 203, or 204 of the third conductive layer. FIG. 24 shows a structure in which the insulating pattern 139d is provided in one or more embodiments, in which the insulating pattern 139b is provided on the connection member 202, 203, or 204 of the third conductive layer.

As shown in FIG. 20 and FIG. 23, the insulating pattern 139d may not be provided.

A thickness in the third direction DR3 of the insulating pattern 139c or 139d may be approximately 1 micrometer to approximately 1.5 micrometer, but the present disclosure is not limited thereto.

The fifth conductive layer may be provided of multiple layers, and may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu). For example, the fifth conductive layer may be provided of a triple layer such as Ti/Al/Ti (e.g., a layer of Ti, a layer of Al, and a layer of Ti).

In the manufacturing method of the display device according to one or more embodiments, the fourth conductive layer may be patterned by a photo-etching process and/or the like after conductive materials are stacked, and if (e.g., when) the fourth conductive layer is provided of multiple layers with different metals, the fourth conductive layer may have a tip shape, in which some layers of the multiple layers protrude more laterally than another layer thereof depending on an etching ratio. For example, if the fourth conductive layer is provided of the triple layer of Ti/Al/Ti (e.g., a layer of Ti, a layer of Al, and a layer of Ti), an etching rate of aluminum (Al) of an intermediate layer may be higher than an etching rate of titanium (Ti), so that the fourth conductive layer has a tip shape, in which an upper layer including titanium (Ti) protrudes more laterally than the intermediate layer. If (e.g., when) the insulating pattern 139c or 139d does not cover an edge of the fourth conductive layer and the fifth insulating layer 134 is directly stacked, the fifth insulating layer 134 including the inorganic insulating material may have a defect, such as a crack and/or the like in the fifth insulating layer 134 due to an upper layer of the fourth conductive layer protruding in the tip shape. Then, the data line 171 of the fourth conductive layer that provides a capacitor (e.g., the input capacitor Cpr) that affects an operation of the pixel circuit and the display quality may be short-circuited with a conductive layer provided thereon (e.g., the conductive layer is on the data line 171), causing leakage to occur.

According to one or more embodiments, the multiple layers of the fourth conductive layer may include a first layer including a first metal and a second layer including a second metal different from the first metal and arranged below the first layer, and an etching rate of the first layer may be lower than an etching rate of the second layer, so that the first layer provides a tip shape at an edge of the fourth conductive layer. For example, the first layer may include titanium (Ti), and the second layer may include aluminum (Al).

However, because the insulating pattern 139c or 139d covers the edge of the fourth conductive layer, the upper layer of the fourth conductive layer protruding in the tip shape may be covered by a relatively thick insulating pattern 139c or 139d including the organic insulating material, so that the fifth insulating layer 134 is protected. Accordingly, the leakage caused by the short circuit between the data line 171 of the fourth conductive layer that provides the capacitor (e.g., the input capacitor Cpr) that affects the operation of the pixel circuit and the display quality and the conductive layer provided thereon may be prevented or reduced. As shown in FIG. 21, even if the edge of the data line 171 covered with the insulating pattern 139c protrudes in a tip shape, a short circuit and leakage between the edge of the data line 171 and the fifth conductive layer adjacent to and arranged above the edge of the data line 171 may be prevented or reduced. An interval between the edge of the data line 171 and the fifth conductive layer adjacent may be indicated by arrow AE3.

As shown in FIG. 22 and FIG. 24, even if the edge of the data line 171 covered with the insulating pattern 139d protrudes in a tip shape, a short circuit and leakage between the edge of the data line 171 and the fifth conductive layer adjacent to and arranged above the edge of the data line 171 may be prevented or reduced. An interval between the edge of the data line 171 and the fifth conductive layer may be indicated by arrow AE4.

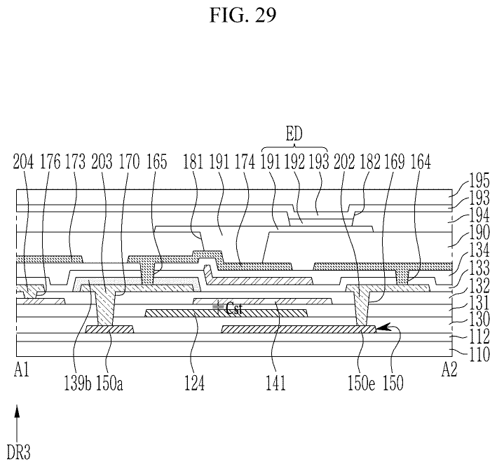

FIGS. 25 to 30 additionally each shows a structure on the fifth conductive layer, and FIG. 31 is a plan view of a plurality of pixel electrodes in a display area of the display device, according to one or more embodiments.

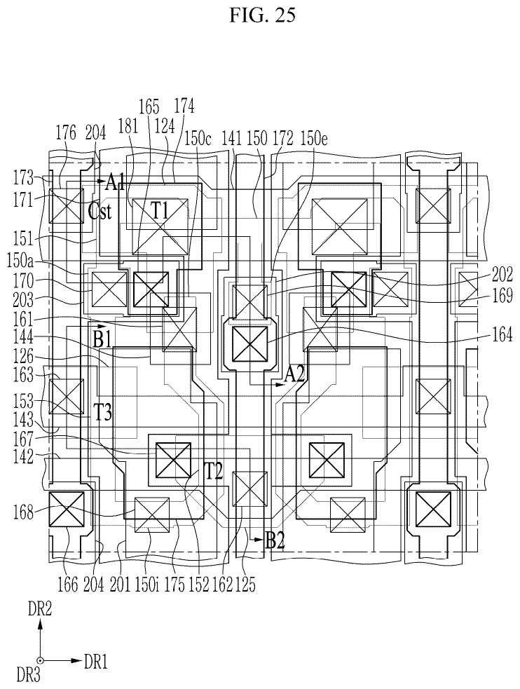

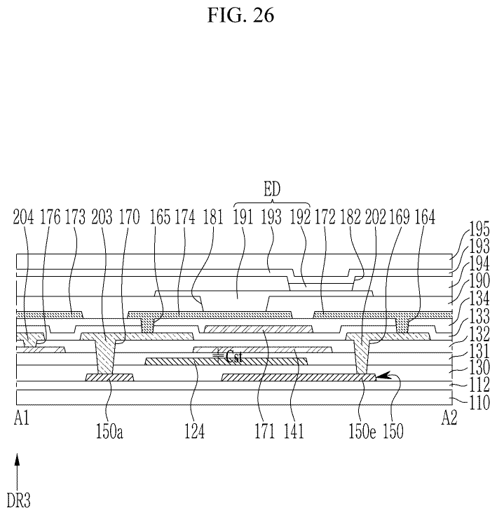

Referring to FIGS. 26 to 30, a sixth insulating layer 190 may be arranged on the fifth conductive layer. The sixth insulating layer 190 may include an organic insulating material, such as a general-purpose polymer (e.g., polymethyl methacrylate (PMMA) or polystyrene (PS)), a polymer derivative having a phenol-based group, an acryl-based polymer, an imide-based polymer, polyimide, a siloxane-based polymer, and/or the like.

The sixth insulating layer 190 may have an opening 181 arranged on the anode connection member 174.

A sixth conductive layer may be arranged on the sixth insulating layer 190. The sixth conductive layer may include a pixel electrode 191. The pixel electrode 191 may function as the anode of the light-emitting element ED. Referring to FIG. 26 and FIG. 31, the pixel electrode 191 may be electrically connected to the anode connection member 174 through the opening 181 of the sixth insulating layer 190 to receive an output current of the first transistor T1.

A seventh insulating layer 194 may be arranged on the pixel electrode 191. The seventh insulating layer 194 is also referred to as a partition wall or a pixel-defining layer. The seventh insulating layer 194 may have a pixel opening 182 arranged on the pixel electrode 191. The pixel opening 182 may define a light-emitting area of each pixel (PX). Each light-emitting area may have a different planar size according to a color that the pixel (PX) represents. Referring to FIG. 31, the pixel opening 182 may not overlap the opening 181 on a plane (e.g., may be spaced from the opening 181 in plan view).

A light-emitting layer 192 may be arranged within the pixel opening 182. The light-emitting layer 192 may include at least one of an organic light-emitting material, an inorganic light-emitting material, and/or a quantum dot that may be a semiconductor nanocrystal. In one or more embodiments, a common layer may be arranged above and/or below the light-emitting layer 192, and the common layer may include a portion arranged on an upper surface of the seventh insulating layer 194 outside the pixel opening 182.

A common electrode 193 may be arranged on the light-emitting layer 192 and the seventh insulating layer 194. The common electrode 193 may function as the cathode of the light-emitting element ED. The common electrode 193 may receive the second driving voltage ELVSS.

The pixel electrode 191, the light-emitting layer 192, and the common electrode 193 may provide the light-emitting element ED that may be a light-emitting diode.

An encapsulation portion 195 may be arranged on the light-emitting element ED to prevent or reduce moisture and/or oxygen penetrating the light-emitting layer 192 from the outside of the display device. The encapsulation portion 195 may include a single layer and/or a single substrate, or may include at least one organic film and at least one inorganic film that are alternately stacked. According to one or more embodiments, the encapsulation portion 195 may have a triple-layer structure provided, for example, in an order of an inorganic film, an organic film, and an inorganic film.

A touch electrode may be provided on the encapsulation portion 195, a polarizing plate, a window, and/or the like may be arranged thereon.

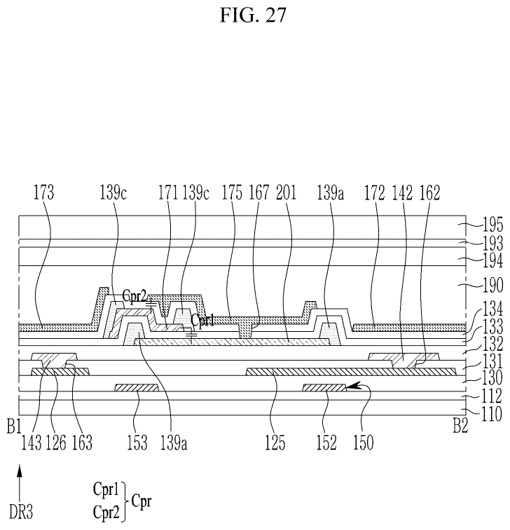

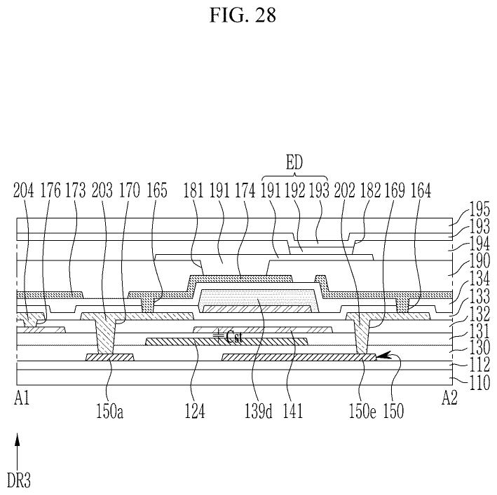

FIG. 26 corresponds to FIG. 20 described above, FIG. 27 corresponds to FIG. 21 described above, FIG. 28 corresponds to FIG. 22 described above, FIG. 29 corresponds to FIG. 23 described above, and FIG. 30 corresponds to FIG. 24 described above.

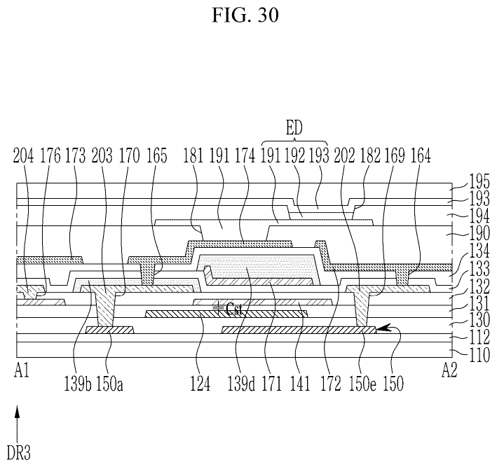

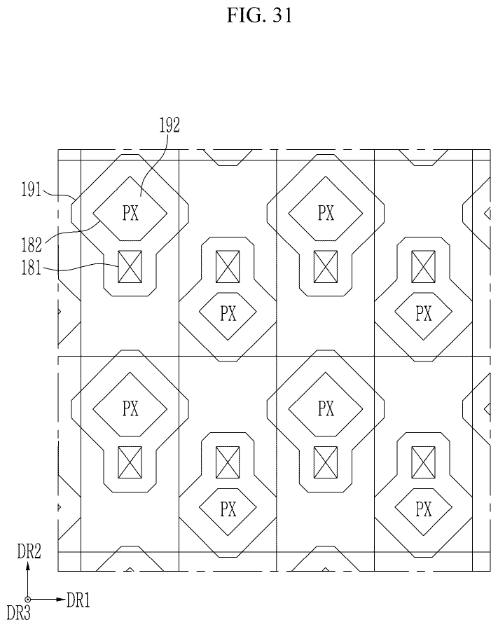

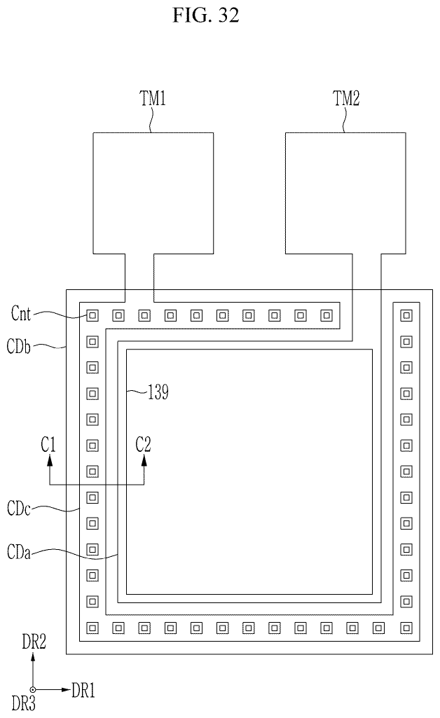

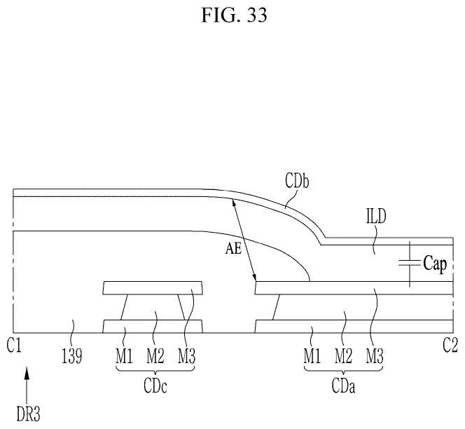

FIG. 32 is a plan view of a conductive layer providing a capacitor of the display device according to one or more embodiments, and FIG. 33 is a cross-sectional view of the display device shown in FIG. 32 cut along a line C1-C2.

Referring to FIG. 32 and FIG. 33, the display device or an electronic device according to one or more embodiments may include a lower conductive layer CDa or CDc and an upper conductive layer CDb arranged on different layers on a substrate, and an insulating layer ILD arranged on the lower conductive layer CDa or CDc. The upper conductive layer CDb may overlap the lower conductive layer CDa with the insulating layer ILD therebetween (e.g., the insulating layer ILD is between the upper conductive layer CDb and the lower conductive layer CDa) to provide a capacitor Cap. The capacitor Cap may be arranged inside a display area including a plurality of pixels where an image is displayed on the display device, or may be arranged in a peripheral area around the display area that does not display an image.

The lower conductive layer CDa may receive a voltage through a terminal TM2, and the upper conductive layer CDb may be electrically connected to the lower conductive layer CDc through a contact hole Cnt to receive a voltage. The upper conductive layer CDb may planarly overlap the lower conductive layer CDc. The lower conductive layer CDc may or may not be arranged on the same conductive layer as the lower conductive layer CDa. The lower conductive layer CDc may receive a voltage through a terminal TM1, and may transfer the received voltage to the upper conductive layer CDb.

The lower conductive layer CDc may be separated from the lower conductive layer CDa, and they may be insulated from each other.

The lower conductive layer CDa or CDc may be provided of a triple layer such as Ti/Al/Ti (e.g., a layer of Ti, a layer of Al, and a layer of Ti). Adjacent layers of the triple layer may include different metals. For example, the lower conductive layer CDa or CDc may include a lower layer M1 including titanium (Ti), an intermediate layer M2 including aluminum (Al), and an upper layer M3 including titanium (Ti).

In a forming process of the lower conductive layer CDa or CDc, after the triple layer is stacked, the triple layer may be patterned by a photo-etching process and/or the like, and because etching ratios of the metals constituting the triple layer are different, the triple layer may have a tip shape, in which the upper layer M3 including titanium (Ti) protrudes more laterally than the intermediate layer M2.

According to one or more embodiments, the multiple layers of the lower conductive layer may include a first layer including a first metal and a second layer including a second metal different from the first metal and arranged below the first layer, and an etching rate of the first layer may be lower than an etching rate of the second layer, so that the first layer provides a tip shape at an edge of the lower conductive layer. For example, the first layer may include titanium (Ti), and the second layer may include aluminum (Al).

An edge of the lower conductive layer CDa providing the capacitor Cap may be covered by an insulating pattern 139, and the insulating layer ILD may be provided on the insulating pattern 139 and the lower conductive layer CDa. The upper conductive layer CDb may be arranged on the insulating layer ILD.

The insulating layer ILD may include an inorganic insulating material, such as silicon oxide (SiOₓ), silicon nitride (SiNₓ), and/or the like. A thickness in the third direction DR3 of the insulating layer ILD may be approximately 1000 angstroms to approximately 2000 angstroms, but the present disclosure is not limited thereto.

The insulating pattern 139 may planarly (in a plan view) overlap and cover at least a portion of the edge of the lower conductive layer CDa. The insulating pattern 139 may be in contact with an upper surface and a side surface of the lower conductive layer CDa at the edge of the lower conductive layer CDa. The insulating pattern 139 may extend (e.g., planarly extend) along the edge of the lower conductive layer CDa to have a closed curve band shape. The insulating pattern 139 may have a width sufficient to cover the edge of the lower conductive layer CDa. The insulating pattern 139 may cover only the edge of the lower conductive layer CDa, may not cover a central portion of the lower conductive layer CDa, and may not planarly overlap the central portion of the lower conductive layer CDa (e.g., may be spaced from the central portion of the lower conductive layer CDa in plan view).

The insulating pattern 139 may include an organic insulating material, such as a general-purpose polymer (e.g., polymethyl methacrylate (PMMA) or polystyrene (PS)), a polymer derivative having a phenol-based group, an acryl-based polymer, an imide-based polymer, polyimide, and/or a siloxane-based polymer.

A thickness in the third direction DR3 of the insulating pattern 139 may be approximately 1 micrometer to approximately 1.5 micrometer, but the present disclosure is not limited thereto. The thickness in the third direction DR3 of the insulating pattern 139 may be greater than a thickness in the third direction DR3 of the insulating layer ILD.

Because the edge of the lower conductive layer CDa is covered by the insulating pattern 139, the insulating layer ILD between an edge where a tip of the lower conductive layer CDa is provided and the upper conductive layer CDb adjacent to and arranged above the lower conductive layer CDa may not be broken, and a short circuit and leakage between the edge and the upper conductive layer CDb may be prevented or reduced. An interval between the edge and the upper conductive layer CDb may be indicated by arrow AE.

The display device according to the above embodiments can be applied to various electronic devices. An electronic device according to an embodiment comprises the aforementioned display device and may further comprise a module or a device with additional functions other than the display device.

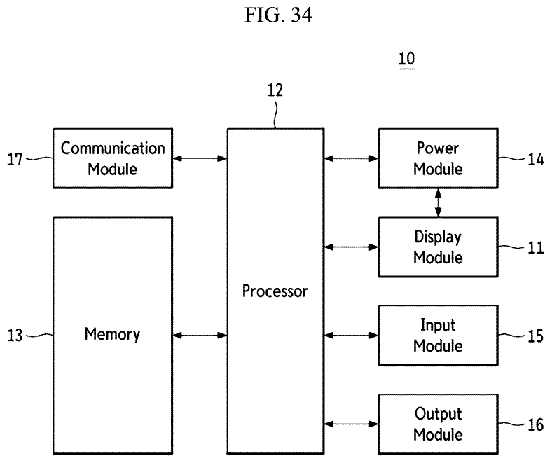

FIG. 34 is a block diagram of an electronic device according to an embodiment. Referring to FIG. 34, an electronic device 10 according to an embodiment may comprise a display module 11, a processor 12, a memory 13, and a power module 14. The electronic device 10 may further comprise an input module 15, a non-visual output module 16, and/or a communication module 17. The display module may comprise a display device according to an embodiment as described above.

The electronic device 10 may output various information in the form of images via the display module 11. When the processor 12 executes an application stored in the memory 13, an image information provided from the application may be provided to a user via the display module 11. The power module 14 may comprise a power supply module such as a power adapter or a battery device, and a power conversion module that converts the power supplied by the power supply module to generate the power necessary for operation of the electronic device 10. The input module 15 may provide an input information to the processor 12 and/or the display module 11. The non-visual output module 16 may receive information other than the image information, such as sound, haptic, or light information provided from the processor 12, and provide it to the user. The communication module 17 is responsible for transmitting and receiving information between the electronic device 10 and an external device, and may comprise a receiver and a transmitter.

At least one of the aforementioned components of the electronic device 11 may be included within the display device according to the above-described embodiments. In addition, some of the individual modules that are functionally included in one module may be included within the display device, while others may be provided separately from the display device. For example, a display device according to an embodiment may include the display module 11, while the processor 12, the memory 13, and the power module 14 may be provided in a form of other devices within the electronic device 11, not within the display device.

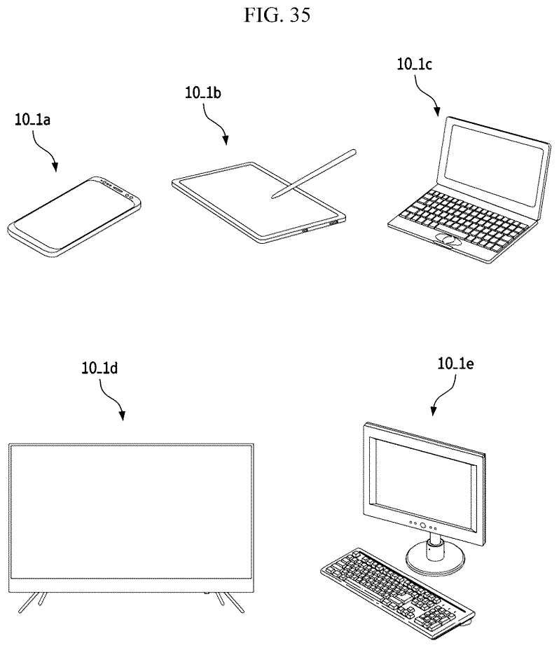

FIG. 35 to FIG. 37 are schematic diagrams of electronic devices according to various embodiments. FIG. 35 to FIG. 37 illustrate examples of various electronic devices to which a display device according to an embodiment is applied.

FIG. 35 illustrates examples of electronic devices, including a smartphone 10_1a, a tablet PC 10_1b, a laptop 10_1c, a TV 10_1d, and a desktop monitor 10_1e.

A smartphone 10_1a may comprise an input module such as a touch sensor and a communication module in addition to the display module 11. The smartphone 10_1a may process information received through the communication module or other input modules and display the information through the display module of the display device.

Each of the tablet PC 10_1b, the laptop 10_1c, the TV 10_1d, and the desktop monitor 10_1e may comprise a display module and an input module similar to the smartphone 10_1a, and may additionally comprise a communication module depending on embodiments.

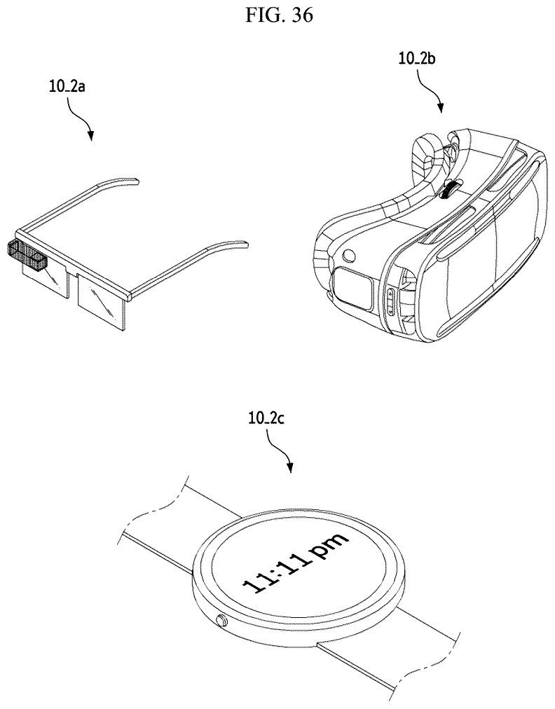

FIG. 36 illustrates an example where an electronic device including a display module is applied to a wearable electronic device. The wearable electronic device may be smart glasses 10_2a, a head-mounted display 10_2b, a smart watch 10_2c, and so on.

The smart glasses 10_2a and the head-mounted display 10_2b may comprise a display module that projects display images and a reflector that reflects the projected display images to provide it to a user's eyes, through which, a screen of virtual reality or augmented reality may be provided to the user.

The smart watch 10_2c may comprise a biometric sensor as an input device, and may provide biometric information recognized through the biometric sensor to a user via a display module.

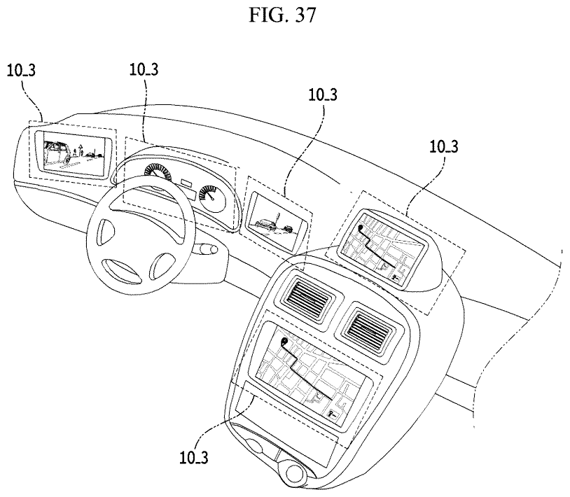

FIG. 37 illustrates an example of an electronic device including a display module applied to a vehicle. For example, an electronic device 10_3 may be applied to an instrument panel, or a center fascia, etc. of a car, or it may be applied to a CID (Center Information Display) placed on a dashboard of a car, or it may be applied to a room mirror display replacing a side mirror.

Although not illustrated, an electronic device to which a display device according to embodiments is applied may include not only devices primarily focused on screen display such as a billboard, an electronic signboard, and a gaming machine, but also various home appliances that display information through a display module, such as a refrigerator, a washing machine, a dryer, an air conditioner, and a robot vacuum cleaner. Furthermore, when the display module has a light-transmitting function, it can be applied to an electronic device such as a smart window or a transparent display device that show both the background and a displayed image. The types of electronic devices according to the embodiments are not limited to the examples given above, and application to various other electronic devices not mentioned may also be possible.

A display device according to one or more embodiments is a device that displays a moving image and/or a still image. The display device may be applied to portable electronic devices such as mobile phones, smartphones, tablet personal computers (PCs), mobile communication terminals, electronic notebooks, electronic books, portable multimedia players (PMPs), navigations, and ultra-mobile PCs (UMPCs). For example, the display device may be applied to a display unit of a television, a laptop computer, a monitor, a billboard, or the Internet of Things (IoT). Alternatively, in one or more embodiments, the display device may be applied to a smartwatch, a watch phone, and/or a head-mounted display device (HMD) for implementing virtual reality and/or augmented reality.

As utilized herein, the terms “substantially,” “about,” and similar terms are utilized as terms of approximation and not as terms of degree, and are intended to account for the inherent deviations in measured or calculated values that would be recognized by those of ordinary skill in the art. “About” or “approximately,” as utilized herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the context of the present disclosure and unless otherwise defined, the terms “use/utilize,” “using/utilizing,” and “used/utilized” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A display device, a device of manufacturing a display device, and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device utilizing a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

While this disclosure has been described in connection with what is presently considered to be practical embodiments, it should be understood that the disclosure is not limited to the disclosed embodiments, but, on the contrary, is intended to cover one or more suitable modifications and equivalent arrangements included within the spirit and scope of the appended claims and equivalents thereof.

### DESCRIPTION OF SYMBOLS

110: substrate 124, 125, 126: gate electrode
130, 131, 132, 133, 134, 190, 194, ILD: insulating layer
139, 139a, 139b, 139c, 139d: insulating pattern
141: horizontal initialization voltage line 142: scan line
143: control signal line 144: connection member
150: semiconductor pattern 150a: anode connection semiconductor
150c: capacitor connection semiconductor
150e: first driving voltage input semiconductor 150i: data voltage input semiconductor
151, 152, 153: semiconductor for transistor
161, 162, 163, 164, 165, 166, 167, 168, 169, 170, 176, 181: opening
171: data line 172: driving voltage line
173: vertical initialization voltage line 174: anode connection member
175: second electrode for input capacitor 182: pixel opening
191: pixel electrode 192: light-emitting layer
193: common electrode 195: encapsulation portion
201: first electrode for input capacitor 202, 203, 204: connection member
CDa, CDb, CDc: conductive layer Cpr, Cpr1, Cpr2: input capacitor
Cst: storage capacitor

What is claimed is:

1. A display device comprising:
a substrate;
a lower conductive layer above the substrate, and comprising a first layer comprising a first metal, and a second layer below the first layer and comprising a second metal different from the first metal, the first layer having a tip shape in which the first layer protrudes laterally further than the second layer at an edge of the lower conductive layer;
a first insulating pattern above the lower conductive layer, and overlapping the edge of the lower conductive layer;
a first insulating layer above the lower conductive layer and the first insulating pattern; and
an upper conductive layer overlapping the lower conductive layer with the first insulating layer therebetween to provide a first capacitor.

2. The display device of claim 1, wherein the first insulating pattern is spaced from a central portion of the lower conductive layer in plan view.

3. The display device of claim 2, wherein the first insulating pattern extends along the edge of the lower conductive layer to provide a closed curved band shape.

4. The display device of claim 3, wherein the first insulating pattern comprises an organic insulating material, and wherein the first insulating layer comprises an inorganic insulating material.

5. The display device of claim 4, wherein a thickness of the first insulating pattern is greater than a thickness of the first insulating layer.

6. The display device of claim 5, wherein the thickness of the first insulating pattern is about 1 micrometer to about 1.5 micrometer.

7. The display device of claim 1, wherein the first layer comprises titanium (Ti), and wherein the second layer comprises aluminum (Al).

8. The display device of claim 1, wherein the lower conductive layer comprises a first capacitor electrode, wherein the upper conductive layer comprises a first voltage line, and wherein the first capacitor electrode and the first voltage line overlap to provide the first capacitor.

9. The display device of claim 8, further comprising:
a second insulating pattern above the upper conductive layer, and overlapping an edge of the upper conductive layer;
a second insulating layer above the upper conductive layer and the second insulating pattern; and
a second capacitor electrode above the second insulating layer,
wherein the upper conductive layer comprises a third layer comprising a third metal, and a fourth layer below the third layer and comprising a fourth metal different from the third metal,
wherein the third layer has a tip shape in which the third layer protrudes laterally further than the fourth layer at the edge of the upper conductive layer, and
wherein the second capacitor electrode overlaps the upper conductive layer with the second insulating layer therebetween to provide a second capacitor.

10. The display device of claim 9, wherein the second insulating pattern is spaced from a central portion of the upper conductive layer in plan view.

11. The display device of claim 10, wherein the second insulating pattern extends along the edge of the lower conductive layer to provide a band shape.

12. The display device of claim 11, wherein the second insulating pattern comprises an organic insulating material, and wherein the second insulating layer comprises an inorganic insulating material.

13. The display device of claim 12, wherein a thickness of the second insulating pattern is greater than a thickness of the second insulating layer.

14. The display device of claim 13, wherein the thickness of the second insulating pattern is about 1 micrometer to about 1.5 micrometer.

15. The display device of claim 9, wherein the third layer comprises titanium (Ti), and wherein the fourth layer comprises aluminum (Al).

16. The display device of claim 9, wherein the second capacitor electrode and the first voltage line overlap to provide the second capacitor.

17. A display device comprising:
a substrate;
pixel circuit portions that are above the substrate;
a voltage line that is electrically connected to the pixel circuit portions;
an input capacitor electrode that overlaps the voltage line with an insulating layer therebetween to provide a capacitor; and
an insulating pattern that overlaps at least one edge of the input capacitor electrode and the voltage line,
wherein at least one of the input capacitor electrode or the voltage line comprises a first layer comprising a first metal, and a second layer below the first layer and comprising a second metal different from the first metal, the first layer having a tip shape in which the first layer protrudes laterally further than the second layer, and the input capacitor electrode having an island shape in the pixel circuit portions.

18. The display device of claim 17, wherein the insulating pattern is spaced from at least one central portion of the input capacitor electrode or the voltage line in plan view.

19. The display device of claim 18, wherein the insulating pattern extends along the at least one edge of the input capacitor electrode and the voltage line to provide a band shape.

20. The display device of claim 19, wherein the insulating pattern comprises an organic insulating material, and wherein the insulating layer comprises an inorganic insulating material.

21. An electronic device comprising a display device comprising:
a substrate;
a lower conductive layer above the substrate, and comprising a first layer comprising a first metal, and a second layer below the first layer and comprising a second metal different from the first metal, the first layer having a tip shape in which the first layer protrudes laterally further than the second layer at an edge of the lower conductive layer;
a first insulating pattern above the lower conductive layer, and overlapping the edge of the lower conductive layer;
a first insulating layer above the lower conductive layer and the first insulating pattern; and
an upper conductive layer overlapping the lower conductive layer with the first insulating layer therebetween to provide a first capacitor.

22. The electronic device of claim 21, wherein the electronic device comprises a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
